(19) United States
(12) Patent Application Publication
(10) Pub. No.: US 2009/0253072 A1
(43) Pub. Date: Oct. 8, 2009

(54) NANOPARTICLE REVERSIBLE CONTRAST ENHANCEMENT MATERIAL AND METHOD

(76) Inventors: Melissa A. Petruska, Newtown, CT (US); Guiquan Pan, Danbury, CT (US); Thomas H. Baum, New Fairfield, CT (US); Karl E. Boggs, Hopewell Junction, NY (US)

Correspondence Address: MOORE & VAN ALLEN PLLC, P.O. BOX 13706, Research Triangle Park, NC, 27709, US

(21) Appl. No.: 12/416,805

(22) Filed: Apr. 1, 2009

Related U.S. Application Data
(60) Provisional application No. 61/041,387, filed on Apr. 1, 2008.

(51) Int. Cl. G03F 7/20; G03F 7/004

(52) U.S. Cl. 430/270.1; 430/322; 977/811

(57) ABSTRACT

The invention is to a reversible photobleachable material comprised of nanoparticles of indium gallium oxide or gallium oxide, and a method of exposing a substrate, such as in semiconductor manufacture, using same.

### FIELD

The present invention generally relates to a reversible photo-bleachable material comprised of nanoparticles of indium gallium oxide or gallium oxide or mixtures thereof, said material useful in microelectronic device photolithography. In one embodiment, the nanoparticles of indium gallium oxide or gallium oxide or mixture thereof are dispersed in an inorganic sol gel including, but not limited to, silica-based sol-gels such as SiO₂ or alumina-based gels. The resultant sol gel can be deposited on a substrate such as a silicon wafer or other electronically viable material, in consort with a photoresist and optionally other barrier layers (e.g., hard coating layers) as required to facilitate processing, so as to permit repeated exposures of incident light having wavelengths such as 248 nm and 193 nm.

### DISCUSSION OF THE BACKGROUND

A given material can be opaque to light of a certain wavelength because it absorbs photons of that particular wavelength. This absorption can induce degradation or saturation of the radiation absorption mechanism thus rendering the material transparent to that same wavelength. This effect is called photo-bleaching and it is of particular interest to the semiconductor industry in the context of photoresists and the like. In this use setting, it is often desirable that the photo-bleaching be reversible, i.e., that the materials recover the original optical property after the radiation is turned off. This relaxation process can happen automatically, or it can be triggered by external conditions such as by the application of electrical or magnetic fields, use of light at different wavelength, heat, etc.

Whereas the photo-bleaching process has a wide range of applications, particular interest lay in the field of microelectronic device manufacture where the effect finds utility in contrast enhancement materials (CEM) used in photolithography. The transparency of a CEM varies directly with the intensity of the incident light, i.e., its ability to absorb photons decreases as incident light promotes electrons in the CEM from the ground state into the excited state. A CEM increases the contrast of the image, resulting in improved resolution and depth of focus and reduced interference. These factors in turn allow the fabrication of denser integrated circuits without additional capital equipment investment.

Because of their unique photochemical and photophysical properties, colloidal, semiconductor nanoparticles (also known as nanocrystals) have size-tunable optical, electronic, and magnetic properties that are not available in the corresponding bulk materials. Specifically for semiconductor nanocrystals, the bandgap shifts to higher energy when the size of the particle is smaller than its exciton Bohr radius. Accordingly, semiconductor nanocrystals—often called quantum dots—have been used for many applications including, but not limited to, optical communications, light-emitting diodes, lasers, photonic chips, photovoltaic devices, photoelectric devices, catalysts, biolabels for bioimaging, sensors, batteries, fuel cells, and the like. Many of these applications do not rely on a single nanocrystal for operation but rather require assembling nanocrystals into larger, robust arrays for convenient device incorporation. One known method of accomplishing this task is by dispersing nanocrystals in a matrix material.

In addition to manifesting photo-bleaching behavior, which permits the benefits aforesaid, it is also advantageous if this behavior is reversible, permitting more flexible processing, e.g., multiple exposures of the microelectronic device wafer without the conventional intermediate steps of removal and re-application of chemicals, which can be more numerous and expensive than those required for reversing the effect in the first instance. Such materials can thus enable certain lithography processes, such as double exposure.

Such reversible contrast enhancement materials (RCEM) employing nanocrystals in lithography are disclosed in US Patent Application Publication 2004/0152011 to Chen et al., the entire contents of which is incorporated herein by reference. Chen et al., describes a contrast enhancement material comprising various nanoparticles immersed in a polymer matrix and other chemicals, wherein the product has use as a photo-bleachable material in optical lithography.

The development of a reversible contrast enhancement material in lithography dictates the need for a material whose absorbance properties can be both photobleached at the wavelength of exposure (e.g., 248 nm or 193 nm) and recovered after the radiation source is removed. Wide bandgap semiconductor nanoparticles satisfy these criteria and have a discrete density of states that allows for photobleaching at reasonable intensities. However, nanoparticles compositions whose bandgaps are at 248 and 193 nm have been relatively unexplored.

### SUMMARY

The present invention generally relates to a nanoparticle-containing material which can be used as a reversible photo-bleachable material in semi-conductor photolithography, including for bandgaps at 248 nm and 193 nm. In one aspect, a reversible photo-bleachable material comprising nanoparticles of indium gallium oxide or gallium oxide or mixtures thereof is described. Such material can be used as a reversible photo-bleachable material in microelectronic device photolithography.

In another aspect, the aforementioned nanoparticles are dispersed in a matrix comprising either a solvent or a sol-gel. Sol-gels in this regard comprise inorganic substances, such as silica (SiO₂) and/or alumina. The amount of nanoparticles present in the sol-gel can vary, but typical loadings are up to about 20% of the final sol gel composition, by volume.

In another aspect, a method of exposing a substrate comprising photoresist to radiation is described, said method comprising (1) providing a layer comprised of indium gallium oxide nanoparticles or gallium oxide nanoparticles or mixtures thereof in a matrix on the substrate; and (2) illuminating the substrate with at least one light pattern wherein the nanoparticles bleach in response to the illumination. In another aspect, the photobleaching is reversible.

In still another aspect, a method of exposing a substrate comprising photoresist to radiation is described, said method comprising (1) depositing a photoresist layer onto the substrate, (2) providing a layer comprised of indium gallium oxide nanoparticles or gallium oxide nanoparticles or mixtures thereof in a matrix on the substrate; and (3) illuminating the substrate with at least one light pattern wherein the nanoparticles bleach in response to the illumination. In another aspect, the photobleaching is reversible. In an alternative embodiment, a hard coating layer is deposited between the photoresist layer and the layer comprising the nanoparticles.

Other aspects, features and advantages will be more fully apparent from the ensuing disclosure and appended claims.

### BRIEF DESCRIPTION OF THE DRAWING

FIG. 1 shows the absorbance spectrum of a material comprising In_{1.1}Ga_{0.9}O₃ dispersed in silica sol gel, wherein the arrow marks the position of the bandgap at 248 nm.

### DETAILED DESCRIPTION OF THE INVENTION

The reversible photo-bleachable material described herein comprises nanoparticles of indium gallium oxide or gallium oxide or mixtures thereof. Indium gallium oxide refers to compounds having the general formula InGaO as understood by the skilled artisan to include various crystalline forms of same. A preferred indium gallium oxide is InₓGa_{y}O₃ wherein x and y are each independently in a range from about 0. 1 to about 1.9; more preferably about 0.9 to about 1.1, with the proviso that in all instances x+y=2.0. Gallium oxide refers to compounds of the general formula GaO, including the various crystalline forms of same. The preferred gallium oxide is Ga₂O₃. Alternatively, or in addition to indium gallium oxide and/or gallium oxide, the nanoparticles may comprise magnesium oxide (MgO), aluminum oxide (Al₂O₃), and/or SiO₂ particles.

As used in the present application, the term “nanoparticle” refers specifically to a particle of the above mentioned compositions having an average size of about 1 nm to about 100 nm, preferably about 1 nm to about 10 nm. Without limitation such sizes include less than about 9 nm; and ranges of about 1 nm to about 8 nm; about 2 nm to about 7 nm; about 3 nm to about 6 nm; and about 5 nm. The terms nanocrystals, nanoparticles, nanodots, nanoflowers, nanomaterials, nanospheres, nanobeads, microcrystallites, nanoclusters, quantum dots, quantum spheres, quantum crystallite, microcrystal, colloidal particle, Q-particle, and nanocubes are to be considered interchangeable. The nanoparticles may be semiconductors, conductors, or dielectrics or they can exhibit other properties of interest, including magnetic and catalytic behavior. The nanoparticles can be crystalline, semi-crystalline, poly-crystalline, or non-crystalline, i.e., amorphous, metal oxide inorganic cores. In addition, it should be appreciated that the term nanoparticles may be used to describe an aggregate or a non-aggregate of inorganic cores of nanometer dimensions. Nanoparticles of less than 10 nm and otherwise can be obtained, for example, using the procedures described in U.S. Patent Application Ser. No. 60/987,988 filed Nov. 14, 2007 entitled “Solvent-Free Synthesis of Soluble Nanocrystals,” and PCT/US08/83592 filed Nov. 14, 2008 having the same title, the entire contents of which are incorporated herein by reference. Other methods of size reduction or sized-synthesis, as known to the skilled artisan, can also be used. As appreciated by the artisan, the bandgaps of the nanoparticles of indium gallium oxide or gallium oxide can be tuned by changing the size of the nanoparticles, e.g., the size of the gallium oxide or indium gallium oxide nanoparticle; or by changing the In:Ga ratio of the nanoparticles, e.g., the In:Ga ratio of the indium gallium oxide mixed metal nanocrystals. In a preferred embodiment, the ratio In:Ga is in a range from about 1:1 to about 1.4:1, preferably about 1.1:1 to about 1.3:1, and most preferably about 1.1:0.9. Generally, as the actual size of the particle decreases, a larger In:Ga ratio is required to obtain the same bandgap position.

For ease of reference, “microelectronic device” corresponds to semiconductor substrates, solar cells (photovoltaics), flat panel displays, and microelectromechanical systems (MEMS), manufactured for use in microelectronic, integrated circuit, or computer chip applications. It is to be understood that the terms “microelectronic device,” “microelectronic substrate” and “microelectronic device structure” are not meant to be limiting in any way and include any substrate or structure that will eventually become a microelectronic device or microelectronic assembly. The microelectronic device can be patterned, blanketed, a control and/or a test device.

As defined herein, a “substrate” corresponds to any material including, but not limited to: bare silicon; polysilicon; germanium; III/V compounds such as aluminum nitride, gallium nitride, gallium arsenide, indium phosphide; titanites; II/IV compounds; II/VI compounds such as CdSe, CdS, ZnS, ZnSe and CdTe; silicon carbide; sapphire; silicon on sapphire; carbon; doped glass; undoped glass; diamond; GeAsSe glass; poly-crystalline silicon (doped or undoped); mono-crystalline silicon (doped or undoped); amorphous silicon, copper indium (gallium) diselenide; and combinations thereof. The substrate can have at least one layer thereon, said layer(s) selected from the group consisting of doped epitaxial silicon, undoped epitaxial silicon, low-k dielectric, high-k dielectric, etch stop material, metal stack material, barrier layer material, a ferroelectric, a silicide, a nitride, an oxide, photoresist, bottom anti-reflective coating (BARC), sacrificial anti-reflective coating (SARC), doped regions, a hard coating layer, and combinations thereof.

As used herein, “about” is intended to correspond to ±5% of the stated value.

As used herein, the “matrix” can correspond to the dispersion of the nanoparticles in a solvent or in a solid material. For example, the solid material may comprise organic compounds, e.g., a polymeric material such as perfluoropolymers, inorganic compounds, e.g., a sol-gel material, e.g., silica and or alumina, or combinations thereof.

As used herein, “dispersed” corresponds to the dispersal of the nanoparticles homogeneously or heterogeneously throughout the matrix. For example, the nanoparticles may be homogeneously dispersed throughout the matrix such that the concentration of nanoparticles at the surface is substantially the same as the concentration at any other sampling location in the layer. Heterogeneous dispersal corresponds to more nanoparticles at one sampling location in the layer relative to some other sampling location in the layer. For example, there may be more nanoparticles at the surface of the matrix relative to other sampling locations or there may be islands of more concentrated nanoparticles throughout the layer.

As used herein, “reversible” can correspond to less than absolute or absolute reversibility. Preferably, the nanoparticles are at least about 90% reversible, preferably at least about 95% reversible, even more preferably at least about 98% reversible, and most preferably at least about 99% reversible. The extent of reversibility is readily determined by one skilled in the art.

In one embodiment, the nanoparticles as described herein are dispersed in a solvent, e.g. a solvent system suitable with the pertaining chemistry of the underlying microelectronic device substrate and layers, e.g., photoresist. Typical solvents include organic solvents such as nonpolar solvents (e.g., hexane, benzene, toluene, pentane, heptane, ethyl acetate, hexanes), ketones (e.g., acetone, 2-butanone, 2-pentanone, and 3-pentanone), ethers (e.g., tetrahydrofuran), amines (e.g., monoethanolamine, triethanolamine, triethylenediamine, methylethanolamine, methyldiethanolamine, pentamethyldiethylenetriamine, dimethyldiglycolamine, 1,8-diazabicyclo[5.4.0]undecene, aminopropylmorpholine, hydroxyethylmorpholine, aminoethylmorpholine, hydroxypropylmorpholine, diglycolamine, N-methylpyrrolidinone (NMP), N-octylpyrrolidinone, N-phenylpyrrolidinone, cyclohexylpyrrolidinone, vinyl pyrrolidinone), amides (e.g., formamide, dimethylformamide, acetamide, dimethylacetamide), sulfur-containing solvents (e.g., tetramethylene sulfone and dimethyl sulfoxide), alcohols (e.g., methanol, ethanol, propanol, butanol, pentanol, hexanol and higher alcohols), glycols (e.g., ethylene glycol, propylene glycol (1,2-propanediol), neopentyl glycol, and benzyl diethylene glycol (BzDG)), polyglycols (e.g., diethylene glycol and higher polyethylene glycols, dipropylene glycol and higher polypropylene glycols), glycol ethers (e.g., diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether (TPGME), propylene glycol monoethyl ether, propylene glycol n-propyl ether, dipropylene glycol n-propyl ether (DPGPE), tripropylene glycol n-propyl ether, propylene glycol n-butyl ether, dipropylene glycol n-butyl ether (DPGBE), tripropylene glycol n-butyl ether, propylene glycol phenyl ether (phenoxy-2-propanol)), and glycerol and the like. In one embodiment, the nanoparticles, which can be employed as-synthesized, are dispersed in said solvent using methods known by the art, e.g., as described in Coe-Sullivan, et al., Advanced Functional Materials, 2005, Vol. 15, pp. 1117-1124; Finlayson, et. al., Advanced Functional Materials, 2002 Vol. 12, pp. 537-540, the entirety of the contents of both herein incorporated by reference. In one preferred approach, the nanoparticles are functionalized with surface capping groups extant on the nanoparticles. Suitable functionalizing ligands include, without limitation, —OH, —COOH, and —Si(OR)₃, in which each R is the same as or different from one another and are selected from hydrogen and a branched or straight-chained C₁-C₆ alkyl group. The resultant dispersion is deposited on the photoresist layer atop a wafer by known methods (e.g. spin coating) whereafter the solvent evaporates leaving the nanoparticles on the photoresist in a ‘neat’ state.

In another embodiment, the nanoparticles as described herein are dispersed in a sol gel. Sol gels contemplated include those comprised of inorganic substances, e.g., silicon-based materials. A preferred sol gel comprises SiO₂. The nanoparticles can be combined with the sol-gel material in a number of different ways known to the artisan. In one preferred approach, the nanoparticles are functionalized consistent with the chemistry of the sol-gel matrix. For example, the surface capping groups extant on the nanoparticles and passivating them are exchanged for ligands that terminate in sol-gel active functionalities. Suitable terminating ligands include, without limitation, —OH, —COOH, and —Si(OR)₃, in which each R is the same as or different from one another and are selected from hydrogen and a branched or straight-chained C₁-C₆ alkyl group. These functionalites then serve as the reactive sites for sol-gel hydrolysis and condensation reactions, giving rise to a nanoparticle/sol-gel composite in which the nanoparticles are intimately connected to the sol-gel network. In one embodiment, nanoparticles comprise about 1% to about 20% by volume of the final sol gel (the loading), including about 10%. Methods useful in making the nanoparticle/sol-gel composite include, without limitation, those described in U.S. Pat. No. 7,190,870 to Sundar et al.; U.S. Pat. No. 7,226,953 to Petruska et al.; Advanced Materials 2002, Vol. 14, pp. 739-743; and Petruska, et al., Advanced Materials, 2003, Vol. 15, pp. 610-613, the entire contents of all of which are incorporated herein by reference. General methods of making the nanoparticle sol-gel composites can also be found in US Patent Application Publication No. 2005/0107478 to Klimov et al., the entire contents of which are incorporated herein by reference.

As aforementioned, a nanoparticle-containing sol-gel material is described herein, specifically a silica sol-gel material comprising indium gallium oxide nanoparticles or gallium oxide nanoparticles or mixtures thereof, wherein the nanoparticles are dispersed in the silica-based sol-gel. This nanoparticle-containing silica sol-gel material can be used as photobleachable contrast enhancement material for optical applications such as photolithography. This material offers several advantages, for example, the sol-gel precursors are inexpensive and are readily available as very pure reagents; moreover, the sol solutions are also extremely processable, offering a wide variety of possibilities in device construction; furthermore, the resulting sol solutions can be spin-coated into planar films or can be dried in various molds, assuming the shape of their containment vessels once the sol hardens into a gel; finally, the surface chemistry of nanoparticles allows them to be incorporated into the sol-gel networks in high volume loading (up to about 20 v/v %) as well-dispersed dopants.

Other variations and options will be appreciated by the artisan, e.g., photoresists operative at 248 nm are typically soluble in alcohols which are often employed in overall processing. In this regard, a barrier layer (e.g., a hard coating layer) as conventionally known is often utilized to prevent unwanted dissolution. In these circumstances, the reversible photo-bleachable material described herein can be deposited on the hard coating layer, if required. Hard coating layers contemplated include, but are not limited to, polymers that are thermally or chemically cross-linkable such as polyvinyl alcohol, silicon oxide underlayers, or silicon nitride underlayers. Conversely, photoresists operative at 193 nm often are not soluble in certain alcohols, and may not require a hard coating layer. The reversible photo-bleachable material described herein can thus be deposited directly on the photoresist in these instances. In addition, the nanoparticles utilized can be coated, e.g., with one or more shell materials, or doped with other elements, all as known in the art. Surfactants and other processing aids may also be used.

In another aspect, a method of using the nanoparticles of indium gallium oxide or gallium oxide or mixtures thereof as a reversible photo-bleachable material in photolithography is described. In one embodiment of the method comprises (1) providing a layer comprising indium gallium oxide nanoparticles or gallium oxide nanoparticles or mixtures thereof on the substrate, wherein the layer can include the matrix of the solvent system or sol gel as supra and the substrate can include, e.g., a silicon wafer having at least a layer of photoresist thereon; and (2) illuminating the photoresist with at least one light pattern wherein the nanoparticles bleach in response to the illumination. The layer of photoresist can be provided by methods known in the art, e.g., spin coating and the illuminating can be provided by methods known in the art, exposure to 193 nm light from an ArF excimer laser.

In a preferred embodiment, a method of exposing a substrate comprising photoresist to radiation is described, said method comprising (1) providing a layer comprising indium gallium oxide nanoparticles or gallium oxide nanoparticles or mixtures thereof in a sol-gel matrix on a substrate; and (2) illuminating the photoresist with at least one light pattern wherein the nanoparticles bleach in response to the illumination. Preferably, the sol-gel comprises SiO₂. In one embodiment, the illuminating comprises providing multiple exposures separated in time.

In another embodiment, a method of exposing a substrate comprising photoresist to radiation is described, the method comprising (1) providing a layer comprising indium gallium oxide nanoparticles or gallium oxide nanoparticles or mixtures thereof which is dissolved in an organic solvent matrix on a substrate; (2) evaporating the organic solvent; and (3) illuminating the photoresist with at least one light pattern wherein the nanoparticles bleach in response to the illumination. In one embodiment, the illuminating comprises providing multiple exposures separated in time.

In another embodiment, a method of exposing a substrate comprising photoresist to radiation is described, said method comprising (1) depositing a photoresist layer onto the substrate, (2) providing a layer comprised of indium gallium oxide nanoparticles or gallium oxide nanoparticles or mixtures thereof in a matrix on the photoresist layer; and (3) illuminating the substrate with at least one light pattern wherein the nanoparticles bleach in response to the illumination. In another aspect, the photobleaching is reversible. In one embodiment, the illuminating comprises providing multiple exposures separated in time.

In still another embodiment, a method of exposing a substrate comprising photoresist to radiation is described, said method comprising (1) depositing a photoresist layer onto the substrate, (2) depositing a hard coating layer onto the photoresist layer, (3) providing a layer comprised of indium gallium oxide nanoparticles or gallium oxide nanoparticles or mixtures thereof in a matrix on the hard coating layer; and (4) illuminating the substrate with at least one light pattern wherein the nanoparticles bleach in response to the illumination. In another aspect, the photobleaching is reversible. In one embodiment, the illuminating comprises providing multiple exposures separated in time.

In any of the aforementioned embodiments, the nanoparticle-containing layer can be allowed to relax between at least some of said exposures. The illuminating radiation can have a wavelength of about 248 nm or about 193 nm.

An advantage of the materials described herein is that film thickness and nanocrystal volume loading can easily be tuned to achieve the desired optical density of the reversible contrast enhancement layer material while at the same time optimizing the Dill parameters and lithographic process window. Moreover, the nanocrystal silica sol-gel composite can be soluble in the developer tetramethylammonium hydroxide (TMAH) and can be removed at the same time the photoresist is developed, circumventing the need for an additional removal step.

The feature and advantages of the invention are more fully shown by the illustrative examples discussed below.

### EXAMPLE 1

To 1 g In_{1.1}Ga_{0.9}O₃ nanocrystals synthesized and isolated as described in U.S. Provisional Patent Appln. No. 60/987,988 supra was added 500 mg hydroxydodecanoic acid and 0.5 mL 1-propanol. After the nanocrystals were dissolved, the mixture was centrifuged to remove insoluble materials. A 20 wt % tetraethylorthosilicate solution in ethanol/water (0.75 mL) was added to the supernatant, and the mixture was stirred for at least one hour and then filtered through a 0.45 micron syringe filter. Films were prepared by spin-coating onto quartz microscope slides for optical absorption measurements (or could be deposited for the reversible contrast enhancement layer application by spin-coating the sol solution on top of a poly(vinylalcohol) hard coating layer/248 nm photoresist stack). The film was hardened by baking at 100° C. for 60 seconds.

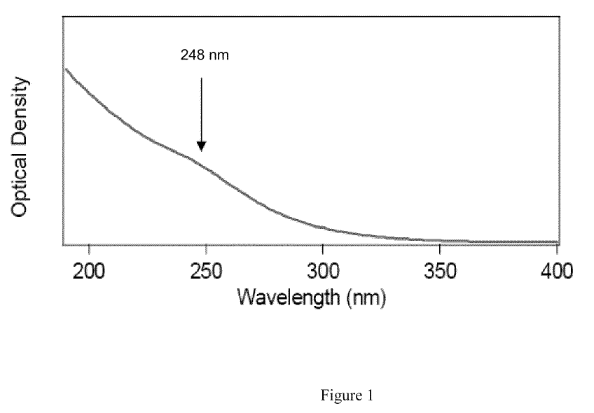

As shown in FIG. 1, the absorbance spectrum of the above prepared In_{1.1}Ga_{0.9}O₃/silica nanocomposite has a bandgap at 248 nm.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

What is claimed is:

1. A reversible photo-bleachable material comprising a matrix having indium gallium oxide nanoparticles or gallium oxide nanoparticles or mixtures thereof dispersed therein.

2. The material of claim 1, wherein said indium gallium oxide nanoparticles have the formula InₓGa_{y}O₃, wherein each of x and y are in the range of about 0.1 to about 1.9, and wherein x+y=2.

3. The material of claim 2, wherein x and y are in the range of about 0.9 to about 1.1, and wherein x+y=2.

4. The material of claim 1, wherein said gallium oxide nanoparticles have the formula Ga₂O₃.

5. The material of claim 1, wherein said nanoparticles are of an average size in a range from about 1 nm to about 10 nm.

6. The material of claim 1, wherein said matrix comprises a sol-gel.

7. The material of claim 6, wherein said sol-gel comprises an inorganic substance.

8. The material of claim 7, wherein said inorganic substance comprises silica.

9. The material of claim 7, wherein said inorganic substance comprises SiO₂.

10. The material of claim 1, wherein said matrix comprises an inorganic solvent.

11. The material of claim 10, wherein the inorganic solvent comprises a species selected from the group consisting of nonpolar solvents, ketones, ethers, amines, amides, sulfur-containing solvents, alcohols, glycols, polyglycols, glycol ethers, and glycerol.

12. The material of claim 1, wherein the nanoparticles are functionalized with terminating ligands selected from the group consisting of —OH, —COOH, and —Si(OR)₃, wherein R is selected from the group consisting of H, a C₁-C₆ alkyl, and combinations thereof.

13. The material of claim 1, wherein the nanoparticles comprise about 1% to about 20% by volume of the material, based on the total volume of the material.

14. The material of claim 1, wherein the nanoparticles comprise In_{1.1}Ga_{0.9}O₃.

15. A method of exposing a substrate comprising a layer of photoresist to radiation, said method comprising:
providing a layer comprising indium gallium oxide nanoparticles or gallium oxide nanoparticles or mixtures thereof in a matrix on the substrate; and
illuminating said photoresist with at least one light pattern wherein said nanoparticles are photo-bleached in response to said illumination.

16. The method of claim 15, wherein said nanoparticles are dispersed in a sol gel matrix.

17. The method of claim 15, wherein said nanoparticles are dispersed in an organic solvent matrix.

18. The method according to claim 15, wherein said illuminating comprising illuminating with radiation having a wavelength of about 248 nm or about 193 nm.

19. The method according to claim 15, wherein the method further comprises depositing a hard coating layer on the photoresist prior to providing a nanoparticle-containing layer on the substrate.

20. The method of claim 15, wherein (i) said nanoparticles comprise Ga₂O₃ and said illuminating occurs at wavelength of 193 nm or (ii) said nanoparticles comprise InₓGa_{y}O₃ wherein each of x and y are in the range of about 0.1 to about 1.9 wherein x+y=2; and wherein said illuminating occurs at a wavelength of 248 nm.
